(19) United States
(12) Patent Application Publication
(10) Pub. No.: US 2011/0243337 A1
(43) Pub. Date: Oct. 6, 2011

(54) AUDIO PROCESSING SYSTEM AND METHOD

(76) Inventors: Carleton H. Huff, Bakersfield, CA (US); David Kerstetter, Thousand Oaks, CA (US); David Eyre, Santa Rosa Valley, CA (US); Francisco J. Pflaum, Westlake Village, CA (US)

(21) Appl. No.: 13/077,588

(22) Filed: Mar. 31, 2011

Related U.S. Application Data
(60) Provisional application No. 61/341,803, filed on Mar. 31, 2010.

(51) Int. Cl. H04R 5/00; H03G 5/00

(52) U.S. Cl. 381/17; 381/103

(57) ABSTRACT

The present invention is a method and system for audio processing. Embodiments of the present invention may include multi-level equalization capabilities along with room optimization, crossovers, switching, automation control, and scene setting. Embodiments of the present invention may be implemented in the analog or digital realms, or both, and may include channel delays, future proof feature slots, and gain and phase inversion capabilities. The present invention may also include an audio optimization system including an audio processing system and a room correction unit. The room correction unit can cooperate with the audio processing system to generate filter coefficients. The filter coefficients are used by the audio processing system when outputting signals which are amplified by an amplifier and broadcast by a speaker to a particular room. The filter coefficients ensure that the outputted sound is optimized for the particular room.

### RELATED APPLICATIONS

This application claims the benefit of U.S. Provisional Patent Application Ser. No. 61/341,803, filed on Mar. 31, 2010, entitled “AUDIO PROCESSING SYSTEM AND METHOD,” which is hereby incorporated by reference in its entirety.

### BACKGROUND

1. Field

The present invention relates to a method and system for audio processing.

2. Description of Related Art

The vast array of audio technologies available to audio professionals has resulted in a dramatic increase in the number of discrete physical items a typical audio professional may utilize in order to maximize the sonic qualities of a particular audio channel or audio environment. A typical palette of tools available to the audio professional manifests itself as numerous separate products with multiple control points that are cumbersome, space consuming and potentially expensive. Thus, it is not uncommon to find an audio professional utilizing half a dozen to a dozen or more rack-mounted pieces of audio gear to achieve desired results in audio processing. The cumbersome, confusing nature of this arrangement often works to the detriment of the audio professional.

Thus, there is a need for a method and system for audio processing that offers a single point of control, offers room optimization technology, is compact, and is capable of being implemented in a cost-effective manner.

### SUMMARY

The present invention is a method and system for audio processing. Embodiments of the present invention can include, for example, multi level equalization capabilities, room optimization, crossovers, switching, automation control, scene setting, channel delays, future proof feature slots, with gain and phase inversion. Embodiments of the present invention may be implemented in either the analog or digital realm, or both.

The present invention can include an audio optimization system having an audio processing system, an amplifier, a speaker, and/or a room correction unit. The audio processing system can transmit signals to the amplifier, which can be amplified before being broadcasted by the speaker. The audio processing system can use filter coefficients to ensure that the signals transmitted to the amplifier are adjusted for the physical dimensions of a room.

The filter coefficients used by the audio processing system are generated by the room correction unit. The room correction unit can control the audio processing system to generate calibration signals, which are amplified and broadcast by the amplifier and the speaker. The room correction unit then analyzes amplified calibration signal data to determine the filter coefficients. The room correction unit allows, for example, for many filter coefficients to be used, which allows for better and finer adjustments to the signal that is outputted by the audio processing system. Furthermore, the use of the room correction unit which automates the generation of the filter coefficients also reduces an amount of time consumed by human personnel in generating filter coefficients. This can reduce a cost of ensuring that the signal that is outputted by the audio processing system is optimized for the particular room.

In one embodiment, the present invention is an audio processing system including a signal processor, multiple input channels formed from an analog input connected to the signal processor, a high definition multimedia interface input connected to the signal processor, and digital inputs connected to the signal processor. The audio processing system can also include multiple output channels connected to the signal processor, wherein any one of the multiple output channels can receive an audio signal from one or more of the multiple input channels.

In another embodiment, the present invention is an audio optimization system including an audio processing system including a signal processor configured to generate a calibration signal, and to generate output signals from input signals using filter coefficients, wherein the filter coefficients provide adjustments in a frequency domain and a time domain to the input signals, and a room correction unit configured to generate the filter coefficients used by the audio processing system.

In yet another embodiment, the present invention is a method for processing audio including generating, using an audio processing system, a calibration signal, generating, using a room correction unit, filter coefficients to provide adjustments in a frequency domain and a time domain to input signals using the calibration signal, and generating, using an audio processing system, output signals from the input signals using the filter coefficients.

### BRIEF DESCRIPTION OF THE DRAWINGS

The features, objects, and advantages of the present invention will become more apparent from the detailed description set forth below when taken in conjunction with the drawings, wherein:

FIG. 1 is a block diagram of an embodiment of the present invention;

FIGS. 2A, 2B, and 2C form a detailed diagram of an embodiment of the present invention;

FIG. 3 is a box diagram of an audio optimization system including an audio processing system and a room correction unit according to an embodiment of the present invention; and

FIG. 4 depicts a process according to an embodiment of the present invention.

### DETAILED DESCRIPTION

The detailed description of exemplary embodiments herein makes reference to the accompanying drawings and pictures, which show the exemplary embodiment by way of illustration and its best mode. While these exemplary embodiments are described in sufficient detail to enable those skilled in the art to practice the invention, it should be understood that other embodiments may be realized and that logical, electrical and mechanical changes may be made without departing from the spirit and scope of the invention. Thus, the detailed description herein is presented for purposes of illustration only and not of limitation. For example, the steps recited in any of the method or process descriptions may be executed in any order and are not limited to the order presented. Moreover, any of the functions or steps may be outsourced to or performed by one or more third parties. Furthermore, any reference to singular includes plural embodiments, and any reference to more than one component may include a singular embodiment.

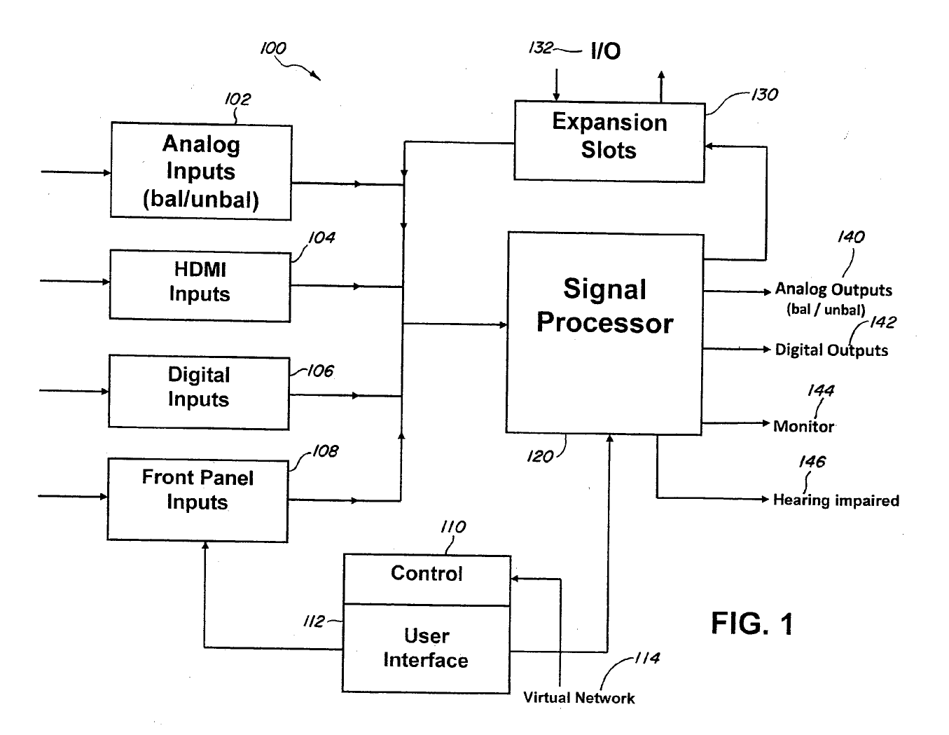

FIG. 1 shows a block diagram of an audio processing system 100 according to an embodiment of the present invention. According to the embodiment shown in FIG. 1, the audio processing system 100 may include analog inputs 102, High Definition Multimedia Interface (“HDMI”) inputs 104, and digital inputs 106. The audio processing system 100 may also include inputs 108 that are available directly from the front panel of the audio processing system 100. Embodiments of the present invention may also include a control mechanism 110, a user interface 112, and a virtual network interface 114. The embodiment of the present invention shown in FIG. 1 may also include a signal processor 120, one or more expansion slots 130 to accommodate growth, other outputs or other inputs, for example, and I/O 132. Embodiments of the present invention may also include analog outputs 140, digital outputs 142, monitor outputs 144, and hearing impaired outputs 146.

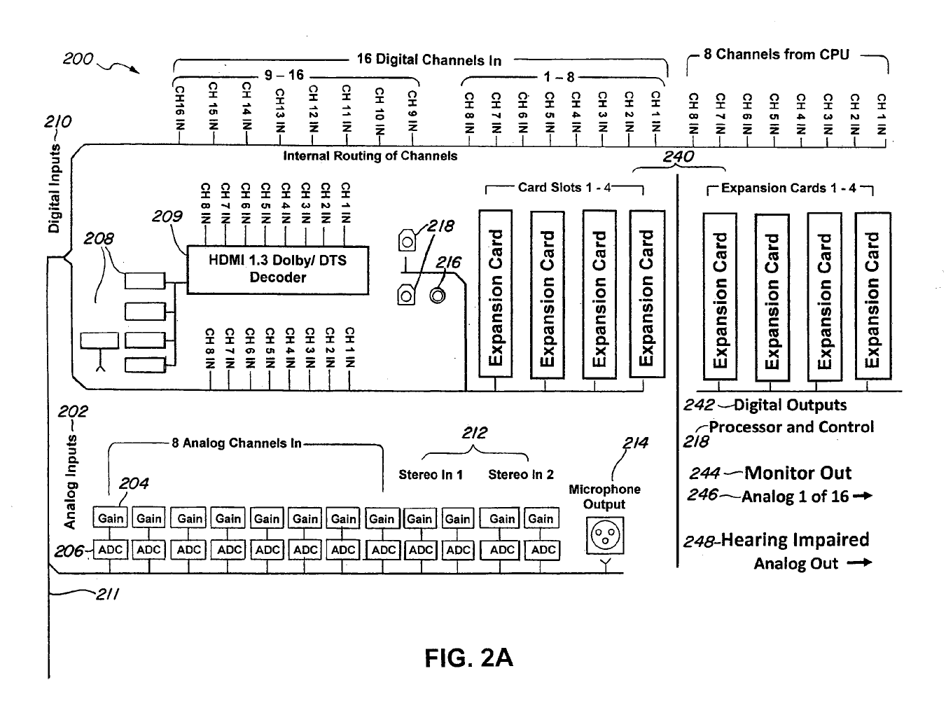

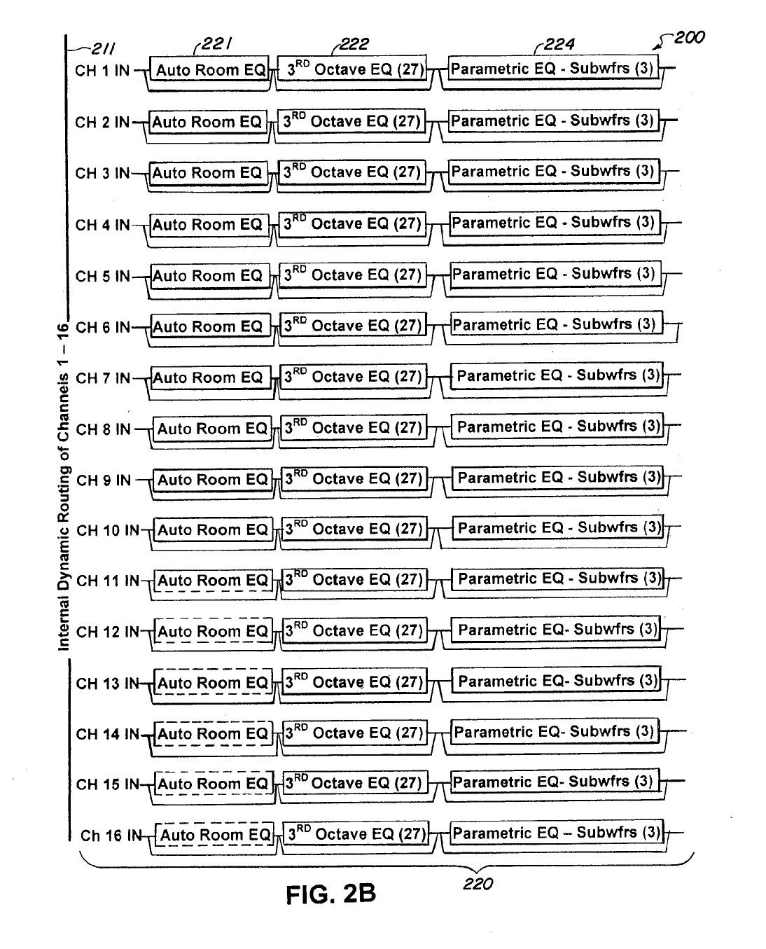

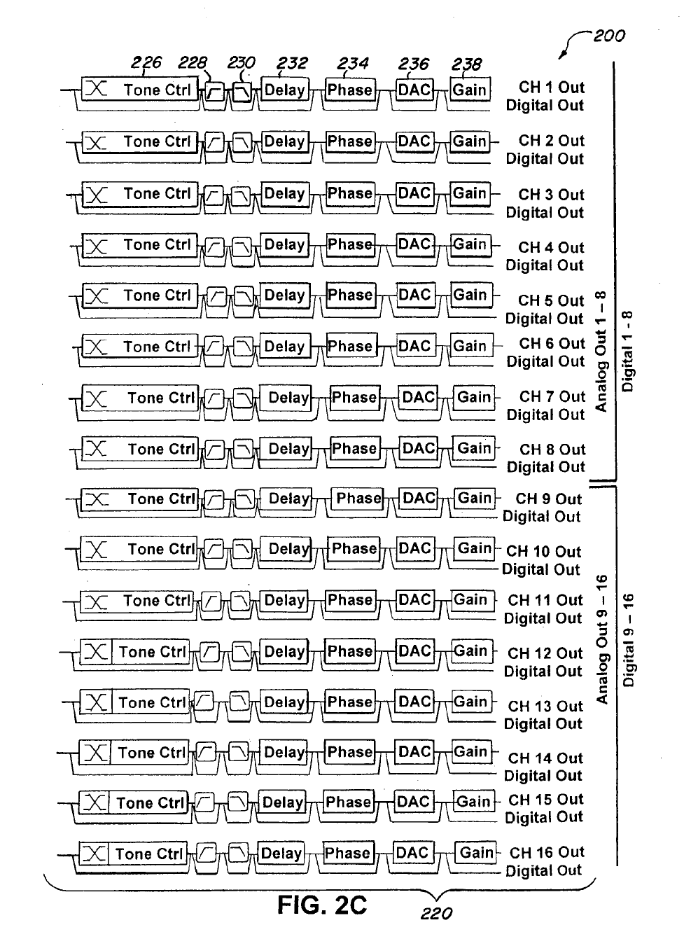

FIGS. 2A, 2B, and 2C show a detailed diagram of an audio processing system 200 according to an embodiment of the present invention. The embodiment of the audio processing system 200 shown in FIGS. 2A, 2B, and 2C may include provision for a variety of different types of analog inputs 202. The analog inputs 202 may be balanced or unbalanced, and may be implemented with a variety of different connector types, such as, for example, a “DB” type connector. In the embodiment shown in FIGS. 2A, 2B, and 2C, the analog inputs 202 are implemented as eight-channel inputs with a DB25 female type connector. The analog inputs 202 may also be implemented with gain control 204 for adjusting the level of the input signal and an analog-to-digital converter 206 for converting an analog input signal into a digital format, thereby making it available for processing by a signal processor 220, as will be discussed in greater detail below.

The embodiment of the audio processing system 200 shown in FIGS. 2A, 2B, and 2C also includes four channels of single ended and routable (non-sync) analog input pairs, configured as 2×2 stereo inputs 212 using RCA type jacks. Also shown in the embodiment of the audio processing system 200 shown in FIGS. 2A, 2B, and 2C is a microphone input 214, configured as single channel, XLR-type male connector.

The embodiment of the audio processing system 200 shown in FIGS. 2A, 2B, and 2C also includes digital inputs 210. The digital inputs 210 may be configured as sixteen channels implemented with a DB25-type female connector, as shown in the embodiment of FIGS. 2A, 2B, and 2C. The internal dynamic routing of channels 1-16 are indicated by the line 211 as shown in FIGS. 2A and 2B. The input channels can be formed, for example, from the analog inputs 102, the HDMI inputs 104, the digital inputs 106, and/or the front panel inputs 108 from the audio processing system 100 shown in FIG. 1. The input channels can be dynamically routed to multiple output channels as shown in FIG. 2B. That is, any output channel can receive its signal from one or more input channels.

Also, the embodiment shown in FIGS. 2A, 2B, and 2C provides for eight of the digital inputs 210 to be available via a front panel, providing ease of use, among other things, for the user. The digital inputs 210 may conform to a variety of electrical and coding formats, such as, for example, the AES/EBU format, and may be sampled at a variety of sampling rates, such as 44.1 kHz, 48 kHz, 96 kHz and 192 kHz. As shown in the embodiment of the invention shown in FIG. 2A, 2B, and 2C, the digital inputs 210 may also be configured as the TOSLINK standard inputs 218, i.e., EIAJ optical, or may be configured as one or more S/PDIF inputs 216.

The embodiment of the audio processing system 200 shown in FIGS. 2A, 2B, and 2C may also include inputs 208 conforming to the HDMI standard. In the embodiment shown, the HDMI inputs 208 are configured as eight audio channels via four HDMI connectors and may also include video pass-thru connectors. Depending on the embodiment, the audio processing system 200 may be configured with an audio decoder 209 that may, for example, be used in conjunction with the data fed through the HDMI inputs 208. According to an embodiment of the present invention, the audio decoder 209 may be configured with any of a variety type of decoding technologies, such as, for example, DOLBY or DTS decoders.

According to an embodiment of the present invention, the audio processing system 200 may be configured with expansion card slots 240 to allow for expansion cards. The expansion card slots 240 allow a user to add a variety of capabilities to the audio processing system 200, such as, for example, additional inputs, additional outputs, wireless and other capabilities.

According to the embodiment of the invention shown in FIGS. 2B and 2C, the audio processing system 200 may be configured with a signal processor 220. The signal processor 220 may be configured as a single processing device or a plurality of processing devices. Moreover, the signal processor 220 may be implemented in hardware, software, firmware or in any combination thereof. The signal processor 220 may be a digital signal processor and may be used to process any of the inputs of the audio processing system 200 shown in the embodiment of the invention of FIGS. 2A, 2B, and 2C.

According to an embodiment of the present invention, the signal processor 220 may include automatic room equalization 221, third or other octave equalization 222, parametric equalization 224, tone control 226, high pass filters 228, low pass filters 230, delay 232, phase adjustment 234, digital-to-analog converters 236 and gain control 238. The parametric equalization 224 is connected to the tone control 226. Any audio processing feature implemented in the signal processor 220 may be bypassed, if desired. Also, embodiments of the present invention allow elements of the signal processor 220 to be configured as a “profile,” i.e., a snapshot of the signal processing. According to embodiments of the present invention, a “profile” may or may not include an input selection or any processing on an input. Thus, a user may configure the signal processor 220 as desired and then set the configuration as a “profile” which may be recalled at a later date and utilized. According to one embodiment of the present invention, the automatic room equalization 221 may be set globally and, thus, is applicable to all inputs, but may change with a profile. Also, the automatic room equalization 221 may be utilized for multiple speakers in a horizontal plane, i.e., surround sound.

According to an embodiment of the present invention, users may also set “formats,” i.e., a combination of a profile, an input selection and any processing on an input. Like profiles, a user may configure the signal processor 220 as desired and then set the configuration as a “format” which may be recalled at a later date and utilized.

According to an embodiment of the present invention, any feature of the audio processing system 200 may be accessed by a control element 219. For example, the control element 219 may be implemented via a front panel touch screen LCD and control knob. Alternatively, any feature of the audio processing system 200 may be accessed remotely, such as through the virtual network 214 shown in FIG. 1. The virtual network 214 allows a user to access and control the audio processing system 200 from any location having access to a network. Also, according to an embodiment of the present invention, a user interface 212 such as that shown in FIG. 1 may be a touch/tactile interface.

The embodiment of the invention shown in FIGS. 2A, 2B, and 2C may be implemented with a variety of outputs. For example, embodiments of the present invention may include digital outputs 242, one or more monitor outputs 244, analog outputs 246 and hearing impaired outputs 248. According to an embodiment of the present invention, the digital outputs 242 may be implemented as sixteen channel outputs, utilizing DB25 type male connectors, and may conform to the AES/EBU format. The digital outputs 242 may support a variety of sampling rates, such as, for example, 44.1 kHz, 48 kHz, 96 kHz and 192 kHz. The analog outputs 246 may be configured as balanced, sixteen channel outputs, utilizing DB25 type male connectors and may be gain-adjustable. According to an embodiment of the present invention, the analog outputs 246 may also be configured as unbalanced (i.e., single-ended), sixteen channel outputs, utilizing DB25 type male connectors and may be gain-adjustable. The monitor output 244 may be configured as, for example, a single ended, channel-selectable RCA output. The hearing impaired output 248 shown in the embodiment of the invention shown in FIGS. 2A, 2B, and 2C may be configured as, for example, a single ended, summed RCA output, and may be gain-adjustable.

According to an embodiment of the present invention, all inputs are fully routable as to their outputs. For example, the routing for any input may be configured as a “one-to-many” configuration, allowing a user to direct any input to one or a plurality of output paths. Also, the routing may be configured as a “many-from-one” configuration for any output, allowing a user to configure any output from one or a plurality of inputs.

The audio processing system 200 shown in FIGS. 2A, 2B, and 2C and the audio processing system 100 shown in FIG. 1 may be used in a variety of applications and venues. For example, a natural application for either the audio processing system 200 shown in FIGS. 2A, 2B, and 2C or the audio processing system 100 shown in FIG. 1 is in an exhibition booth at a movie theater. Embodiments of the present invention may also be used in concert halls, television studios, recording studios, broadcast studios, amusement parks, special venues, home theaters, home and professional audio systems, and the like. Embodiments of the present invention provide the audio professional or other user with a complete set of integrated audio tools that will accommodate all audio and video playback needs.

Embodiments of the invention such as the audio processing system 200 shown in FIGS. 2A, 2B, and 2C and the audio processing system 100 shown in FIG. 1 solve a variety of problems for an audio professional. For example, embodiments of the invention solve the problem of having to use multiple types of audio and other equipment and eliminate the need to upgrade to various and multiple types of equipment in the future as new technologies are developed. For example, using an embodiment of the present invention, an audio professional or other user may sonically optimize a movie theater for maximum audio fidelity using the automatic room equalization 221 feature which previously was not achievable in a single device. Embodiments of the invention also solve the problem of needing multiple controls by virtue of utilizing a single, visual and easy to use LCD or other display type control panel with a single rotary encoder knob.

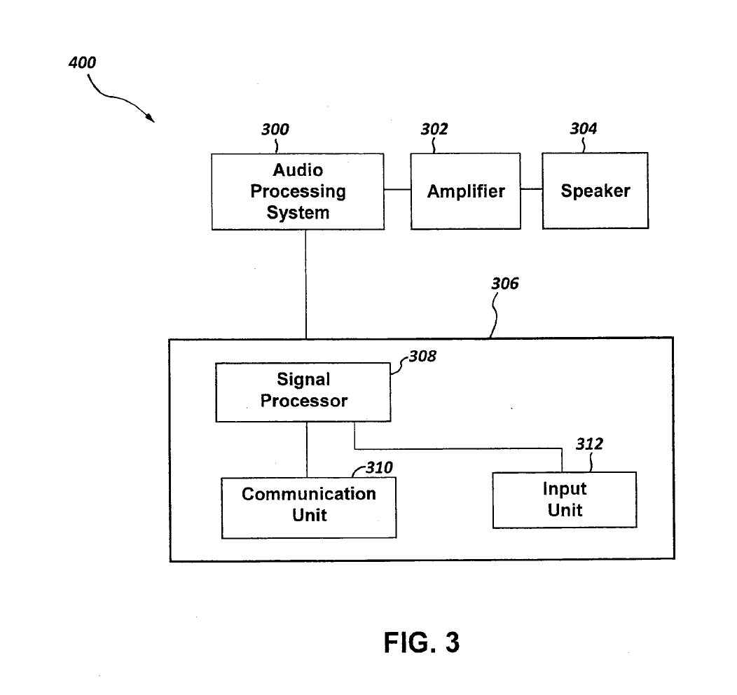

In one embodiment, the present invention can include an audio optimization system 400 as shown in FIG. 3. The audio optimization system 400 can include an audio processing system 300 and/or a room correction unit 306. The audio processing system 300 can be, for example, the audio processing systems 100 and/or 200. The audio processing system 300 can be connected, for example, to an amplifier 302, and/or a speaker 304. The audio processing system 300 can transmit signals to the amplifier 302, which are then amplified before being outputted by the speaker 304. In one embodiment, the audio processing system 300 can transmit, for example, a calibration signal. The calibration signal can be amplified by the amplifier 302 before being outputted by the speaker 304.

The room correction unit 306 can receive the amplified calibration signal and use the amplified calibration signal to generate filter coefficients. In one embodiment, the room correction unit 306 can include, for example, a signal processor 308, a communications unit 310, and/or an input unit 312. The input unit 312 can receive acoustic data. The acoustic data can be, for example, the amplified calibration signal which can be stored as amplified calibration signal data. In one embodiment, the input unit 312 can be, for example, a microphone. In one embodiment multiple input units 312 can be used by the room correction unit 306. The signal processor 308 can analyze the amplified calibration signal data to determine the filter coefficients.

The analysis performed by the signal processor 308 can allow for more filter coefficients to be used, thereby allowing for greater and finer adjustments of the signal outputted by the audio processing system 300. Furthermore, the automation of the analysis of the filter coefficients reduces an amount of time required to adjust the signal output of the audio processing system 300 to ensure that the signal output by the audio processing system 300 is optimized for the particular room that the audio processing system 300 will be working in.

The signal processor 308 can use, for example, the communications unit 310 to transmit the filter coefficients to the audio processing system 300. In one embodiment, the communications unit 310 can be configured for a wired or wireless connection. The audio processing system 300 can use the filter coefficients to perform the automatic room equalization 221 feature described above. In one embodiment, the signal processor 308 and/or the room correction unit 306 can control the audio processing system 300, the amplifier 302, and/or the speaker 304 to generate the amplified calibration signal.

In one embodiment the generation of the filter coefficients can be an iterative process. For example, the signal processor 308 and/or the room correction unit 306 can control the audio processing system 300, the amplifier 302, and/or the speaker 304 to generate a first amplified calibration signal. The input unit 312 located at a first location in a room can receive the first amplified calibration signal and store it as a first amplified calibration signal data. The room can be, for example, a theatre. The signal processor 308 uses the first amplified calibration signal data to calculate the filter coefficients. The input unit 312 can be moved to a second location in the room, or an additional input unit 312 located at the second location in the room can be used.

The signal processor 308 and/or the room correction unit 306 can then control the audio processing system 300, the amplifier 302, and/or the speaker 304 to generate a second amplified calibration signal. The second amplified calibration signal can be, for example, the same as the first amplified calibration signal. The input unit 312 at the second location in the room can receive the second amplified calibration signal and store it as a second amplified calibration signal data. The signal processor 308 then uses the second amplified calibration signal data to further calculate the filter coefficients. The process can be repeated for additional amplified calibration signals and/or additional locations in the room as necessary. In one embodiment, multiple input units 312 are set up at various locations in the room and only a single amplified calibration signal is outputted by the audio processing system 300, the amplifier 302, and/or the speaker 304. Each of the multiple input units 312 receive the single amplified calibration signal and store it as amplified calibration signal data. The amplified calibration signal data for each of the multiple input units 312 are then processed linearly or in parallel by the signal processor 308 to generate the filter coefficients.

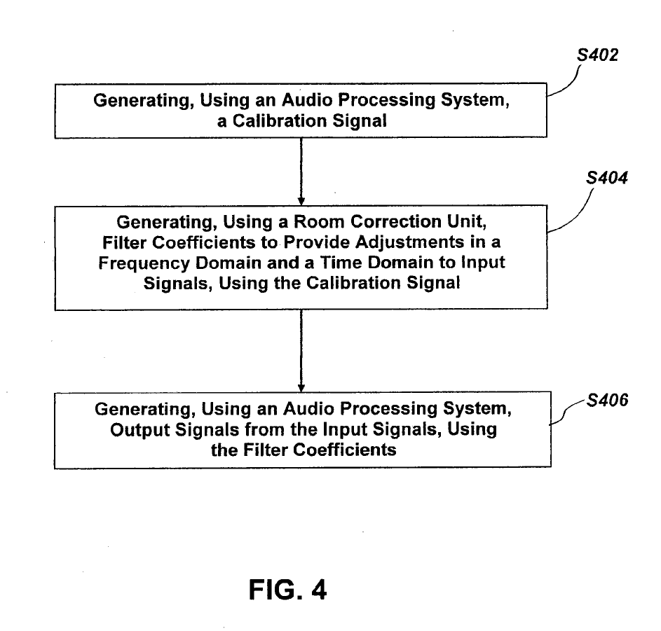

In one embodiment, the present invention can include, for example, a process as shown in FIG. 4. In Step S402, a calibration signal is generated using an audio processing system. For example, the audio processing system 300 can generate an calibration signal. In Step S404, filter coefficients are generated using a room correction unit to provide adjustments in a frequency domain and a time domain to input signals using the calibration signal. For example, the room correction unit 306 can generate filter coefficients using the calibration signal. The filter coefficients can provide adjustments in frequency domain and a time domain to input signals. In Step S406, output signals are generated, using an audio processing system from the input signals using the filter coefficients. For example, the audio processing system 300 can receive the filter coefficients from the room correction unit 306. The audio processing system can receive input signals and generate output signals by applying the filter coefficients to the input signals.

Those of ordinary skill in the art would appreciate that the various illustrative logical blocks, modules, and algorithm steps described in connection with the examples disclosed herein may be implemented as electronic hardware, computer software, or combinations of both. Furthermore, the present invention can also be embodied on a machine readable medium causing a processor or computer to perform or execute certain functions.

To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the disclosed apparatus and methods.

The various illustrative logical blocks, units, modules, and circuits described in connection with the examples disclosed herein may be implemented or performed with software, a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the examples disclosed herein may be embodied directly in hardware, in a software module executed by a processor, or in a combination of the two. The steps of the method or algorithm may also be performed in an alternate order from those provided in the examples. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a wireless modem. In the alternative, the processor and the storage medium may reside as discrete components in a wireless modem.

The previous description of the disclosed examples is provided to enable any person of ordinary skill in the art to make or use the disclosed methods, system and apparatus. Various modifications to these examples will be readily apparent to those skilled in the art, and the principles defined herein may be applied to other examples without departing from the spirit or scope of the disclosed method and apparatus. The described embodiments are to be considered in all respects only as illustrative and not restrictive and the scope of the invention is, therefore, indicated by the appended claims rather than by the foregoing description. All changes which come within the meaning and range of equivalency of the claims are to be embraced within their scope. The previous description of the disclosed examples is provided to enable any person of ordinary skill in the art to make or use the disclosed methods and apparatus. Various modifications to these examples will be readily apparent to those skilled in the art, and the principles defined herein may be applied to other examples without departing from the spirit or scope of the disclosed method and apparatus. The described embodiments are to be considered in all respects only as illustrative and not restrictive and the scope of the invention is, therefore, indicated by the appended claims rather than by the foregoing description. All changes which come within the meaning and range of equivalency of the claims are to be embraced within their scope.

What is claimed is:

1. An audio processing system comprising:
a signal processor;
multiple input channels formed from
an analog input connected to the signal processor,
a high definition multimedia interface input connected to the signal processor, and
digital inputs connected to the signal processor; and
multiple output channels connected to the signal processor, wherein any one of the multiple output channels can receive an audio signal from one or more of the multiple input channels.

2. The system of claim 1 wherein the analog input is balanced or unbalanced.

3. The system of claim 1 wherein the analog input includes a gain control unit or an analog-to-digital converter.

4. The system of claim 1 further comprising a control unit connected to the signal processor.

5. The system of claim 1 further comprising a touch screen monitor connected to the signal processor.

6. The system of claim 1 further comprising expansion card slots connected to the signal processor.

7. The system of claim 1 wherein the signal processor is configured to perform at least one of automatic room equalization, third octave equalization, parametric equalization, or tone control.

8. The system of claim 1 wherein the signal processor includes at least one of a high pass filter, a low pass filter, a delay, a phase adjustment unit, a digital-to-analog converter, or a gain control.

9. An audio optimization system comprising:
an audio processing system including a signal processor configured to generate a calibration signal, and to generate output signals from input signals using filter coefficients, wherein the filter coefficients provide adjustments in a frequency domain and a time domain to the input signals; and
a room correction unit configured to generate the filter coefficients used by the audio processing system.

10. The system of claim 9 wherein the audio processing system further includes multiple input channels formed from
an analog input connected to the signal processor,
a high definition multimedia interface input connected to the signal processor, and
digital inputs connected to the signal processor; and multiple output channels connected to the signal processor, wherein any one of the multiple output channels can receive an audio signal from one or more of the multiple input channels.

11. The system of claim 9 wherein the audio optimization system further comprises
an amplifier, amplifying the calibration signal; and
a speaker to output the amplified calibration signal.

12. The system of claim 11 wherein the room correction unit receives acoustic data, analyzes the acoustic data, and generates the filter coefficients based on the acoustic data.

13. The system of claim 12 wherein the acoustic data is the amplified calibration signal.

14. The system of claim 12 wherein the room correction unit includes a microphone to receive the acoustic data.

15. A method for processing audio comprising:
generating, using an audio processing system, a calibration signal;
generating, using a room correction unit, filter coefficients to provide adjustments in a frequency domain and a time domain to input signals using the calibration signal; and
generating, using an audio processing system, output signals from the input signals using the filter coefficients.

16. The method of claim 15 further comprising amplifying, using an amplifier, the calibration signal.

17. The method of claim 16 further comprising outputting, using a speaker, the amplified calibration signal.

18. The method of claim 17 further comprising
receiving, using the room correction unit, acoustic data;
analyzing, using the room correction unit, the acoustic data; and
generating, using the room correction unit, the filter coefficients based on the acoustic data.

19. The method of claim 18 wherein the acoustic data is the amplified calibration signal.

20. The method of claim 19 further comprising, receiving, using a microphone, the acoustic data.
